(19) United States
(12) Patent Application Publication
(10) Pub. No.: US 2026/0353849 A1
(43) Pub. Date: Nov. 5, 2026

(54) SOLAR CELL

(71) Applicant: EXTRATERRESTRIAL POWER PTY LTD, New South Wales (AU)

(72) Inventor: Bram HOEX, New South Wales (AU)

(73) Assignee: EXTRATERRESTRIAL POWER PTY LTD, New South Wales (AU)

(21) Appl. No.: 19/124,621

(22) PCT Filed: Oct. 30, 2023
(86) PCT No.: PCT/IB2023/060902

§ 371 Date: Apr. 25, 2025

(30) Foreign Application Priority Data
Oct. 31, 2022 (GB) 2216076.6

(51) Int. Cl. H10F 71/00; H10F 10/14; H10F 77/14; H10F 77/30; H10F 77/70

(52) U.S. Cl. CPC H10F 71/129; H10F 10/14; H10F 71/128; H10F 77/311; H10F 77/148; H10F 77/703

(57) ABSTRACT

A solar cell having a hydrogen barrier layer and a hydrogen-containing dielectric layer is provided. A method of making a solar cell, and a solar cell obtained or obtainable by such a method, are also provided.

### TECHNICAL FIELD

In general terms the present invention provides a solar cell comprising a hydrogen barrier layer and a hydrogen-containing dielectric layer. The present invention also provides a method of making a solar cell, and a solar cell obtained or obtainable by such a method.

### BACKGROUND

Activities in space are increasing exponentially in recent years, which translates to a very high demand for energy in space. Solar cells provide one possible means to address this rapid growth in energy demand.

Existing space multijunction (III-V) solar cells are three orders of magnitude more expensive than other types of current terrestrial solar cells, and face challenges in large scale manufacturing due to highly complex manufacturing processes, and expensive and scarce materials. Silicon-based solar cells are manufactured in giga-watt scale for the terrestrial market due to the use of abundant materials and simple fabrication process. However, their performance is lower than III-V cells and they are more heavily degraded by space radiation, leading to a very short lifetime when used in space activities.

There remains a need for solar cells that are suitable for use in space applications, that are more resistant to degradation from space radiation, and which are able to be manufactured more cheaply and at scale.

### SUMMARY OF INVENTION

A first aspect of the invention is a solar cell comprising a Si wafer and a dielectric layer deposited on said Si wafer, wherein the dielectric layer comprises a hydrogen-containing dielectric material; and the solar cell further comprising a first hydrogen barrier layer deposited on the dielectric layer.

A second aspect of the invention is a method of manufacturing a solar cell, said method comprising depositing a first hydrogen barrier layer on a dielectric layer, wherein the dielectric layer comprises a hydrogen-containing dielectric material.

A third aspect of the invention is a solar cell obtained or obtainable by the method as hereinbefore defined.

### BRIEF DESCRIPTION OF FIGURES

FIG. 1 illustrates two exemplary process flows for the manufacture of self-healing solar cells according to the present invention, using hydrogen barrier layers.

FIG. 2 illustrates a schematic of a solar cell according to the invention, resulting from the second exemplary process flow of FIG. 1.

FIG. 3 illustrates a schematic of the hydrogen distribution in a solar cell according to the present invention before and after a high-temperature firing step.

FIG. 4 illustrates the minority charge carrier lifetime of a symmetrical silicon test sample as a function of dark annealing time for samples that received various doses of 1 MeV electrons. The lifetime of the radiated samples increases after dark annealing, indicating that solar cells can ‘self-heal’ radiation-induced defects.

FIG. 5 illustrates the simulated efficiency as a function of the bulk minority carrier lifetime. Simulations were done using Quokka 3. The lifetime shown in FIG. 4 directly affects the efficiency of the solar cell.

### DETAILED DESCRIPTION OF THE INVENTION

A first aspect of the invention is a solar cell comprising a Si wafer and a dielectric layer deposited on said Si wafer, wherein the dielectric layer comprises a hydrogen-containing dielectric material; and the solar cell further comprising a first hydrogen barrier layer deposited on the dielectric layer.

Hydrogen has been used for passivation purposes in terrestrial solar cells since the 2000s. It is commonly supplied to the cell by hydrogen-containing dielectric layers (often used as an antireflection coating), which is activated by a fast-firing process. However, too much hydrogen can have detrimental effects to the solar cell performance (WO2018094462A1). Applying an AlOx layer on top of the hydrogen-containing dielectric layer blocks hydrogen from escaping to the environment during the firing step, and therefore, increases the hydrogen content in the Si bulk. This may result in lower beginning-of-life (BoL) cell efficiency and significantly enhanced light induced degradation due to light and elevated temperature induced degradation (LeTID) (Varshney, U., et al., Controlling Light- and Elevated-Temperature-Induced Degradation With Thin Film Barrier Layers. IEEE Journal of Photovoltaics, 2020. 10(1): p. 19-27). Therefore, this approach is considered undesirable and not recommended for the manufacture of Si-based solar cells.

However, in the context of the space environment, the increased concentration of hydrogen in the bulk means that radiation-induced damage can be repaired more effectively through hydrogen passivation. Despite the potential lower initial BoL efficiency, this method enhances the cell's ability to self-heal from radiation and leads to a better EOL efficiency which is the most important metric for space solar cells.

An object of the present invention is therefore to deliberately increase the bulk hydrogen content in silicon solar cells to promote their self-healing ability in response to space radiation, therefore increasing their lifetime and end-of-life (EoL) performance. This approach is counter-intuitive in the technical field, as a high hydrogen concentration is generally seen as detrimental to the performance of solar cells, as discussed above.

In the solar cell as hereinbefore described, the Si wafer is preferably a p-type Si wafer, an n-type Si wafer, or an intrinsic Si wafer. Particularly preferably the Si wafer is a p-type Si wafer, as this results in increased radiation tolerance.

The solar cell preferably further comprises at least one contact, and preferably comprises contacts for both electrons and holes. The at least one contact preferably comprises poly-Si/SiOx, an aluminium alloy, phosphorous-diffused silicon, gallium-doped or boron-diffused silicon. For the avoidance of doubt, any other suitable contact material known to the skilled person may be used.

In the solar cell according to the invention, the first hydrogen barrier layer preferably comprises SiOx, SiNx, SiC, TiOx, MgFx, TaN, FeOx, ZrOx, or AlOx.

A particularly preferred material for the first hydrogen barrier layer is AlOx. Thus, the first hydrogen barrier layer preferably comprises AlOx. More preferably, the first hydrogen barrier layer consists essentially of AlOx. Still more preferably, the first hydrogen barrier layer consists of AlOx.

The first hydrogen barrier layer functions to prevent the release of hydrogen from the hydrogen-containing dielectric material during the manufacture of the solar cell. In doing so, the hydrogen released from the hydrogen-containing dielectric material during manufacturing is forced to migrate until the Si wafer. Thus the bulk hydrogen content of the Si wafer is increased, resulting in the improved EoL properties of the solar cell described above.

It is therefore a requirement of the first hydrogen barrier layer that it comprises a material that is relatively impermeable to hydrogen (i.e. molecular hydrogen) under the conditions used to manufacture the solar cell.

As such, in the solar cell of the invention, preferably the first hydrogen barrier layer has a first hydrogen permeation rate, and the hydrogen-containing dielectric layer has a second hydrogen permeation rate; wherein the first hydrogen permeation rate is lower than the second hydrogen permeating rate by a factor of at least ten. Preferably the first hydrogen permeation rate is lower than the second hydrogen permeating rate by a factor of at least twenty, at least fifty, or at least one hundred.

The first hydrogen barrier layer preferably has a pinhole density of from 10-1000/mm², preferably from 20-800/mm², more preferably from 50-500/mm² and still more preferably from 75-250/mm², e.g. about 25, about 50, about 75, about 100, about 125, about 150, about 175, about 200, about 225, or about 250/mm². A lower pinhole density is advantageous, as it correlates to a reduced permeation rate for hydrogen (e.g. molecular hydrogen) through the first hydrogen barrier layer.

The first hydrogen barrier layer preferably has a thickness of between 0.1 and 200 nm, preferably between 1 and 50 nm. More preferably the first hydrogen barrier layer has a thickness of between 2 and 40 nm, still more preferably between 3 and 30 nm, even more preferably between 4 and 20 nm, and yet more preferably between 5 and 15 nm. The first hydrogen barrier layer preferably has a thickness of about 1 nm, about 2 nm, about 3 nm, about 4 nm, about 5 nm, about 6 nm, about 7 nm, about 8 nm, about 9 nm, about 10 nm, about 11 nm, about 12 nm, about 13 nm, about 14 nm, about 15 nm, about 20 nm, about 25 nm, about 30 nm, about 40 nm, or about 50 nm.

The first hydrogen barrier layer must have a thickness that is sufficiently large to display the hydrogen barrier properties described above (e.g., low permeability to hydrogen under solar cell manufacturing conditions). However, it will be understood that increasing the thickness of any layer in a solar cell will result in a corresponding increase in size, weight, cost, and manufacturing time (and therefore throughput), and that any layer having a relatively high thickness may therefore be undesirable. It has surprisingly been found that in the present invention, a hydrogen barrier layer as thin as about 10 nm is sufficient to produce the desired hydrogen barrier properties.

Thus in one embodiment of the invention, the first hydrogen barrier layer has a thickness of about 10 nm. Preferably, the first hydrogen barrier layer having a thickness of about 10 nm comprises AlOx, more preferably consists essentially of AlOx and still more preferably consists of AlOx.

The first hydrogen barrier layer may be deposited by any suitable method, e.g. any suitable method for the deposition of thin layers. Such methods are known to the skilled person, and include—but are not limited to—vacuum thermal evaporation, electron beam evaporation, laser beam evaporation, arc evaporation, molecular beam epitaxy, ion plating evaporation, direct current sputtering (DC sputtering), radio frequency sputtering (RF sputtering), sol-gel techniques, chemical bath deposition, spray pyrolysis technique, electroplating, electroless deposition, chemical vapor deposition (CVD), low pressure chemical vapor deposition (LPCVD), plasma enhanced chemical vapor deposition (PECVD), and atomic layer deposition (ALD)

The first hydrogen barrier layer is preferably deposited by atomic layer deposition (ALD). It has surprisingly been found by the present inventors that the use of atomic layer deposition for the deposition of the first hydrogen barrier layer produces a hydrogen barrier layer that has low permeability to hydrogen (e.g., molecular hydrogen) during solar cell manufacturing (i.e., under typical solar cell manufacturing conditions). Without wishing to be bound by theory, it is thought that the use of ALD for the deposition of the first hydrogen barrier layer results in a thin, uniform layer with low pinhole density and resulting low hydrogen (e.g., molecular hydrogen) permeability.

In preferred solar cells as described herein, the first hydrogen barrier layer is deposited directly on the dielectric layer. By “deposited directly on” it is meant that there are no intervening layers between the first hydrogen barrier layer and the dielectric layer.

The solar cell of the invention comprises a dielectric layer, wherein the dielectric layer comprises a hydrogen-containing dielectric material. The hydrogen-containing dielectric material preferably comprises hydrogen in the range of from 5 to 40%, by atomic percentage. In other words, the hydrogen-containing dielectric material preferably has a hydrogen concentration in the range of 5 to 40%. It has surprisingly been found that using precursors for the hydrogen-containing dielectric material that are hydrogen containing, and furthermore not taking steps to reduce, substantially remove or entirely remove the precursor-derived hydrogen can advantageously result in hydrogen passivation of the Si wafer during subsequent manufacturing steps, as described above.

The dielectric layer may be a single layer, or may comprise a stack of multiple dielectric thin films. Preferably the dielectric layer is a single layer.

The hydrogen-containing dielectric material preferably comprises TiO₂, SiN, SiOₓN_{y}, SiOx, SiC, TiOₓ, ZrOₓ or SiC. In one particularly preferred embodiment, the hydrogen-containing dielectric material comprises SiN. More preferably, the hydrogen-containing material consists essentially of SiN. Even more preferably, the hydrogen-containing material consists of SiN. The solar cell may further comprise a second hydrogen barrier layer, wherein the second hydrogen barrier layer is not in direct contact with the first hydrogen barrier layer. By “not in direct contact with” it is meant that at least one intervening layer, and preferably a plurality of intervening layers, are present between the first hydrogen barrier layer and the second hydrogen barrier layer.

For example, the second hydrogen barrier layer may be deposited on the opposite face of the Si wafer from the dielectric layer, such that the solar cell comprises, sequentially, a first hydrogen barrier layer, a dielectric layer, a Si wafer, and a second hydrogen barrier layer. In this arrangement, the second hydrogen barrier layer may advantageously prevent the hydrogen from the hydrogen-containing dielectric material from migrating out of the Si wafer. In the solar cell according to the invention, the second hydrogen barrier layer preferably comprises SiOx, SiNx, SiC, TiOx, MgFx, TaN, FeOx, ZrOx, or AlOx.

A particularly preferred material for the second hydrogen barrier layer is AlOx. Thus, the second hydrogen barrier layer preferably comprises AlOx. More preferably, the second hydrogen barrier layer consists essentially of AlOx. Still more preferably, the second hydrogen barrier layer consists of AlOx.

The second hydrogen barrier layer has a third hydrogen permeation rate, wherein the third hydrogen permeation rate is lower than the second hydrogen permeating rate by a factor of at least ten. Preferably the third hydrogen permeation rate is lower than the second hydrogen permeating rate by a factor of at least twenty, at least fifty, or at least one hundred.

The second hydrogen barrier layer preferably has a pinhole density of from 10-1000/mm², preferably from 20-800/mm², more preferably from 50-500/mm² and still more preferably from 75-250/mm², e.g. about 25, about 50, about 75, about 100, about 125, about 150, about 175, about 200, about 225, or about 250/mm². A lower pinhole density is advantageous, as it correlates to a reduced permeation rate for hydrogen (e.g., molecular hydrogen) through the second hydrogen barrier layer.

The second hydrogen barrier layer preferably has a thickness of between 0.1 and 200 nm, preferably between 1 and 50 nm. More preferably the second hydrogen barrier layer has a thickness of between 2 and 40 nm, still more preferably between 3 and 30 nm, even more preferably between 4 and 20 nm, and yet more preferably between 5 and 15 nm. The second hydrogen barrier layer preferably has a thickness of about 1 nm, about 2 nm, about 3 nm, about 4 nm, about 5 nm, about 6 nm, about 7 nm, about 8 nm, about 9 nm, about 10 nm, about 11 nm, about 12 nm, about 13 nm, about 14 nm, about 15 nm, about 20 nm, about 25 nm, about 30 nm, about 40 nm, or about 50 nm.

The second hydrogen barrier layer may be deposited by any suitable method, e.g., any suitable method for the deposition of thin layers. Such methods are known to the skilled person, and include—but are not limited to—vacuum thermal evaporation, electron beam evaporation, laser beam evaporation, arc evaporation, molecular beam epitaxy, ion plating evaporation, direct current sputtering (DC sputtering), radio frequency sputtering (RF sputtering), sol-gel techniques, chemical bath deposition, spray pyrolysis technique, electroplating, electroless deposition, chemical vapor deposition (CVD), low pressure chemical vapor deposition (LPCVD), plasma enhanced chemical vapor deposition (PECVD), and atomic layer deposition (ALD).

The second hydrogen barrier layer is preferably deposited by atomic layer deposition (ALD).

A second aspect of the invention is a method of manufacturing a solar cell, said method comprising depositing a first hydrogen barrier layer on a dielectric layer, wherein the dielectric layer comprises a hydrogen-containing dielectric material. Preferably the method of manufacturing a solar cell is a method for manufacturing a solar cell as hereinbefore described.

The method preferably comprises a step wherein the first hydrogen barrier layer is deposited directly on the dielectric layer. By “deposited directly on” it is meant that there are no intervening layers between the first hydrogen barrier layer and the dielectric layer.

The first hydrogen barrier layer may be deposited by any suitable method, e.g., any suitable method for the deposition of thin layers. Such methods are known to the skilled person, and include—but are not limited to—vacuum thermal evaporation, electron beam evaporation, laser beam evaporation, arc evaporation, molecular beam epitaxy, ion plating evaporation, direct current sputtering (DC sputtering), radio frequency sputtering (RF sputtering), sol-gel techniques, chemical bath deposition, spray pyrolysis technique, electroplating, electroless deposition, chemical vapor deposition (CVD), low pressure chemical vapor deposition (LPCVD), plasma enhanced chemical vapor deposition (PECVD), and atomic layer deposition (ALD).

The first hydrogen barrier layer is preferably deposited by atomic layer deposition (ALD). It has surprisingly been found by the present inventors that the use of atomic layer deposition for the deposition of the first hydrogen barrier layer produces a hydrogen barrier layer that has low permeability to hydrogen (e.g. molecular hydrogen) during solar cell manufacturing (i.e. under typical solar cell manufacturing conditions). Without wishing to be bound by theory, it is thought that the use of ALD for the deposition of the first hydrogen barrier layer results in a thin, uniform layer with low pinhole density and resulting low hydrogen (e.g. molecular hydrogen) permeability.

A particularly preferred material for the first hydrogen barrier layer is AlOx. Thus, the first hydrogen barrier layer preferably comprises AlOx. More preferably, the first hydrogen barrier layer consists essentially of AlOx. Still more preferably, the first hydrogen barrier layer consists of AlOx.

Thus in a preferred method of the invention, the method comprises a step of depositing AlOx by atomic layer deposition (ALD) on the dielectric layer, preferably directly on the dielectric layer.

The method as hereinbefore described preferably further comprises a bulk hydrogen injection step after the deposition of the first hydrogen barrier layer, wherein the bulk hydrogen injection step comprises heating the solar cell at a temperature of between 400 and 900 °C, preferably between 500 and 800 °C. The temperature range is chosen to be sufficient to cause the migration (e.g. diffusion) of hydrogen from the hydrogen-containing dielectric into the Si wafer, while also not damaging any other material or component of the solar cell.

Thus in preferred methods of the invention, the hydrogen-containing dielectric material comprises hydrogen in the range of from 5 to 40%, by atomic percentage. In other words, the hydrogen-containing dielectric material preferably has a hydrogen concentration in the range of 5 to 40%.

The hydrogen-containing dielectric material preferably comprises TiO₂, SiN, SiOₓN_{y}, SiOx, SiC, TiOₓ, ZrOₓ or SiC. In one particularly preferred embodiment, the hydrogen-containing dielectric material comprises SiN. More preferably, the hydrogen-containing material consists essentially of SiN. Even more preferably, the hydrogen-containing material consists of SiN.

A third aspect of the invention is a solar cell obtained or obtainable by the method as hereinbefore described. Preferably the solar cell obtained or obtainable by this method is a solar cell as hereinbefore described.

### EXAMPLES

### Preparative Example

A full-size as-cut commercial p-type silicon wafer of 0.5-3 ohm. cm resistivity, 180-micron thickness was used. First, the wafer surface was cleaned from contaminants and saw damage resulting from the wafer slicing process. This was done using a wet chemistry process called saw damage removal, where a heated alkaline etch (potassium chloride, KOH) was used to remove several micrometres of surface silicon.

After a rinse in deionized (DI) water and an acid clean (hydrofluoric acid and hydrochloric acid mixtures), the wafer then went through another heated alkaline bath (KOH based) in which random pyramidal structures are formed on the surfaces. These surface features are about 3 microns in size and create a textured surface that reduces light reflectance from the wafer surface.

Immediately after, a room-temperature mild alkaline etch was used to remove several nanometres of the surface silicon and DI water rinse. This was then followed by a series of cleaning processes—such as RCA clean (RCA1+RCA2+HF dip) or room-temperature acid mixtures of HF and HCl—to prepare the wafer for the next high temperature step called emitter diffusion.

In this step, a phosphorus source, POCl₃, in a gaseous form was deposited onto the wafer surfaces inside a furnace heated to temperatures well above 750 °C. The phosphorus contained in this source layer was then driven into the surfaces of and thereby doped the original p-type silicon, converting it into n-type, in the presence of oxygen and driving—in temperatures around 850 °C. This created an emitter—the phosphorus-doped silicon layer of approximately less than 500 nm thick. The phosphorus-containing source deposited on the wafer surface is known as phosphorus silicate glass, which was removed in an HF dip. This wet process is often the start of another series of wet etches involving a mixture of concentrated acids (nitric acid (HNO₃)+HF+acetic acid), a dilute KOH etch, and the cleaning series as described earlier. A DI water rinse was always incorporated between chemical etches. The concentrated acid mixture was applied only on the rear side of the wafer to remove the n-type silicon layer from the rear surface and the wafer edges, practically planarizing these surfaces. Typically, a few micrometres of silicon was etched from these regions. The front side was either kept intact throughout or was allowed to be etched very slightly (less than few nanometres) by the chemical vapour produced in the bath. This process—edge isolation—is important for removing shunting paths and therefore must be uniform and well-controlled.

After this last cleaning process, the wafer went into another furnace where a thin oxide layer was grown at about 700 °C before going through a plasma-enhanced chemical vapour deposition (PECVD) tool. Here, its front surface (the emitter or n-type side) was coated with an 80 nm layer of silicon nitride (SiNx) which acts as a hydrogen-containing source and anti-reflection coating (ARC) to further increase light absorption in the silicon bulk. The rear side was also deposited with hydrogen-containing dielectric layer including a few to few tens of nanometres of aluminium oxide (AlOx) and capped by an about 120 nm layer of SiNx.

To create local contact points for the rear surface, a laser was used to locally remove the rear dielectric layers in either dot or line patterns. Aluminium paste was then screen printed onto the entire rear side and dried before the front side was screen printed with a silver contact grid pattern. The wafer then went into a belt furnace, where the screen-printed contact metals were further dried and driven in to form ohmic contacts with underlying silicon, forming a completed solar cell device.

The solar cell device was then placed into an atomic layer deposition (ALD) tool to deposit a hydrogen barrier layer on the surfaces of the cell. An AlOx layer of a few to a hundred nanometres thick was used. Due to the slow deposition rate, it is preferable to deposit a thinner layer for higher throughput. However, the actual required thickness depends on the final application of the device. For a hydrogen barrier, a layer as thin as 10 nm is sufficient. The cell was then passed through a belt furnace where it was subjected to a temperature within the range of 500 to 800 °C to activate the hydrogen from the hydrogen-containing dielectric layers and inject the mobile hydrogen atoms in their appropriate form into the bulk to effectively passivate bulk defects.

### Alternative Preparation Method

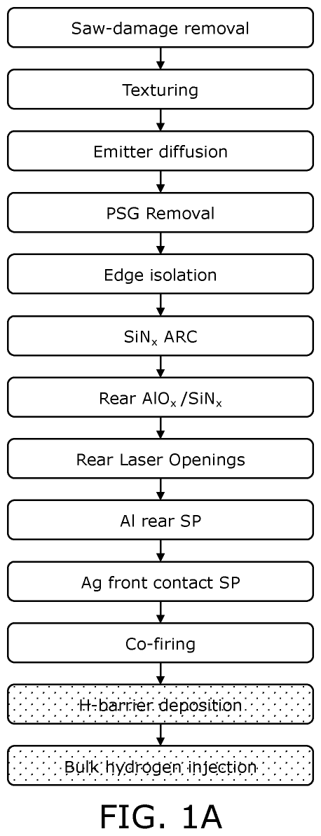

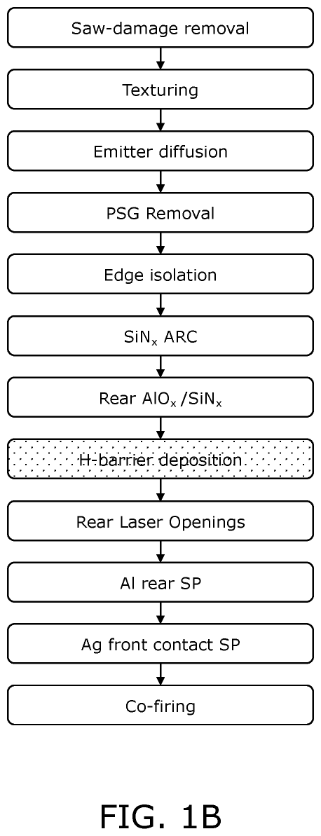

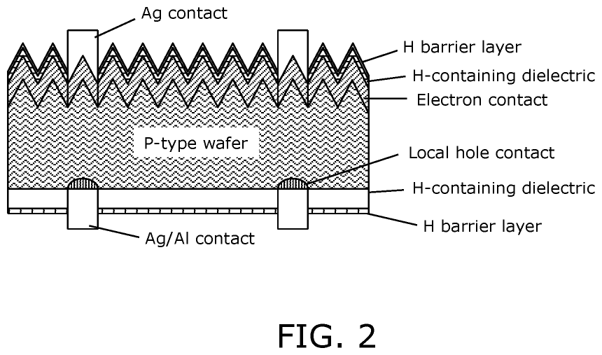

In the second method of implementation (Process flow B), the hydrogen barrier layer was deposited after the rear dielectric depositions, as seen in FIG. 1(B). This was then followed by the standard fabrication sequence as described above. An advantage of this approach is that the hydrogen bulk injection is combined with the co-firing step where metal contacts are formed, therefore reducing the cost of manufacturing.

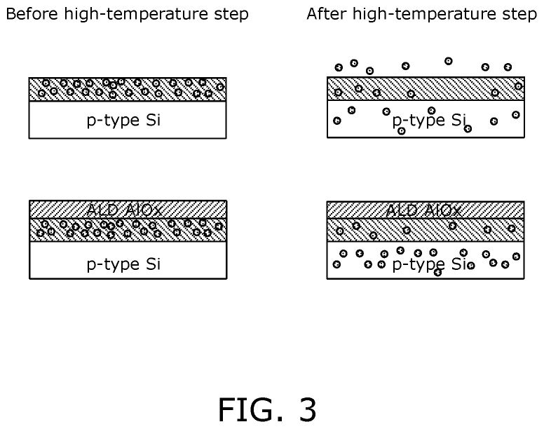

Without wishing to be bound by theory, this method is expected to result in higher concentration of hydrogen injected into the bulk compared to the first method. This is because once the hydrogen atoms in the dielectric layers are activated in this firing step, they are prevented from escaping into the environment due to the presence of the ALD AlOx layer, which forces them to penetrate more into the silicon bulk. In the first method of implementation (Process flow A), a certain amount of hydrogen will be lost into the environment in the co-firing step, making less hydrogen available for the bulk hydrogen injection step at the end (see FIG. 3).

### Experimental Results

In terms of device efficiency, the presence of more hydrogen in the bulk may result in a lower beginning-of-life (BoL) efficiency. However, the resulting increased concentration of hydrogen in the bulk boosts the cell's ability to heal the damage caused by space radiation, thereby increasing its end-of-life (EoL) efficiency.

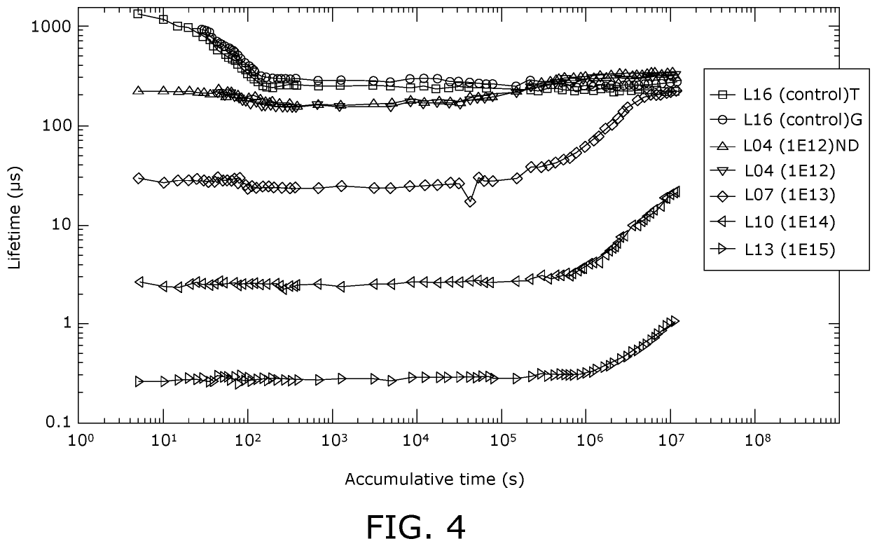

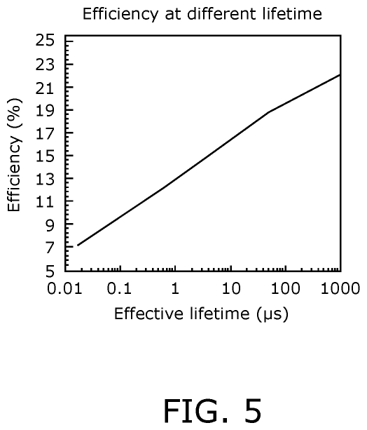

An experiment was conducted where Passivated Emitter and Rear Contact (PERC) lifetime test structure samples were fabricated as described above and irradiated by 1 MeV electrons of varying fluence from 1×10¹² to 1×10¹⁵ electrons/cm². This test structure is necessary to determine the quality of the wafer, its lifetime, which is directly related to its potential cell efficiency, as illustrated by FIG. 5. The samples were subsequently dark annealed and their lifetimes regularly monitored to study the healing effect. As seen in FIG. 4, those samples exposed to 1×10¹² electrons/cm² have shown significant recovery.

We have shown that even the relatively low amount of hydrogen, that is available in the silicon bulk in the first method, is able to heal radiation-induced defects (FIG. 4) and thus increase the performance of the solar cell (FIG. 5). Thus the inclusion of a hydrogen barrier layer deposited on a dielectric layer comprising a hydrogen-containing dielectric results in improved EoL efficiency of a solar cell, by self-healing defects caused by exposure caused by extraterrestrial radiation.

1. A solar cell comprising a Si wafer and a dielectric layer deposited on said Si wafer,
wherein the dielectric layer comprises a hydrogen-containing dielectric material; and the solar cell further comprising a first hydrogen barrier layer deposited on the dielectric layer.

2. The solar cell according to claim 1, wherein the Si wafer is a p-type Si wafer, an n-type Si wafer, or an intrinsic Si wafer.

3. The solar cell according to claim 2, wherein the Si wafer is a p-type Si wafer.

4. The solar cell according to claim 1, further comprising at least one contact, wherein said at least one contact comprises poly-Si/SiOx, an aluminium alloy, phosphorous-diffused silicon, gallium-diffused or boron-diffused silicon.

5. The solar cell according to claim 1, wherein the first hydrogen barrier layer comprises SiOx, SiNx, SiC, TiOx, MgFx, TaN, FeOx, ZrOx, or AlOx.

6. The solar cell according to claim 5, wherein the first hydrogen barrier layer comprises AlOx.

7. The solar cell according to claim 5, wherein the first hydrogen barrier layer consists of AlOx.

8. The solar cell according to claim 1, wherein the first hydrogen barrier layer has a first hydrogen permeation rate, and the hydrogen-containing dielectric layer has a second hydrogen permeation rate; wherein the first hydrogen permeation rate is lower than the second hydrogen permeating rate by a factor of at least ten.

9. The solar cell according to claim 1, wherein the first hydrogen barrier layer has a pinhole density of from 10-1000/mm2, preferably from 20-800/mm2.

10. The solar cell according to claim 1, wherein the first hydrogen barrier layer has a thickness of between 0.1 and 200 nm, preferably between 1 and 50 nm.

11. The solar cell according to claim 1, wherein the first hydrogen barrier layer is deposited by atomic layer deposition (ALD).

12. The solar cell according to claim 1, wherein the first hydrogen barrier layer is deposited directly on the dielectric layer.

13. The solar cell according to claim 1, wherein the hydrogen-containing dielectric material comprises hydrogen in the range of from 5 to 40%, by atomic percentage.

14. The solar cell according to claim 1, wherein the hydrogen-containing dielectric material comprises TiO2, SiN, SiOxNy, SiOx, SiC, TiOx, ZrOx or SiC.

15. The solar cell according to claim 1, wherein the hydrogen-containing dielectric material comprises SiN.

16. The solar cell according to claim 1, further comprising a second hydrogen barrier layer, wherein the second hydrogen barrier layer is not in direct contact with the first hydrogen barrier layer.

17. The solar cell according to claim 16, wherein the second hydrogen barrier layer comprises AlOx, preferably wherein the second hydrogen barrier layer consists of AlOx.

18. The solar cell according to claim 16, wherein the second hydrogen barrier layer has a third hydrogen permeation rate; wherein the third hydrogen permeation rate is lower than the second hydrogen permeating rate by a factor of at least ten.

19. The solar cell according to claim 16, wherein the second hydrogen barrier layer has a pinhole density of from 10-1000/mm2, preferably from 20-800/mm2.

20. The solar cell according to claim 16, wherein the second hydrogen barrier layer has a thickness of between 0.1 and 200 nm, preferably between 1 and 50 nm.

21. The solar cell according to claim 16, wherein the second hydrogen barrier layer is deposited by atomic layer deposition (ALD).

22. A method of manufacturing a solar cell, said method comprising depositing a first hydrogen barrier layer on a dielectric layer, wherein the dielectric layer comprises a hydrogen-containing dielectric material.

23. The method according to claim 22, wherein the first hydrogen barrier layer is deposited directly on the dielectric layer.

24. The method according to claim 22, wherein the first hydrogen barrier layer is deposited by atomic layer deposition (ALD).

25. The method according to claim 22, wherein the first hydrogen barrier layer comprises AlOx, preferably wherein the first hydrogen barrier layer consists of AlOx.

26. The method according to claim 22, further comprising a bulk hydrogen injection step after the deposition of the first hydrogen barrier layer, wherein the bulk hydrogen injection step comprises heating the solar cell at a temperature of between 400 and 900 °C, preferably between 500 and 800 °C.

27. The method according to claim 22, wherein the hydrogen-containing dielectric material comprises hydrogen in the range of from 5 to 40%, by atomic percentage.

28. The method according to claim 22, wherein the hydrogen-containing dielectric material comprises TiO2, SiN, SiOxNy, or SiC.

29. The method according to claim 22, wherein the hydrogen-containing dielectric material comprises SiN.

30. A solar cell obtained or obtainable by the method of claim 22.
